(19) United States
(12) Patent Application Publication
(10) Pub. No.: US 2024/0332388 A1
(43) Pub. Date: Oct. 3, 2024

(54) METHODS OF REDUCING BACKSIDE CONTACT RESISTANCE

(71) Applicant: Applied Materials, Inc., Santa Clara, CA (US)

(72) Inventors: Byeong Chan Lee, San Jose, CA (US); Benjamin Colombeau, San Jose, CA (US); Nicolas Breil, Alviso, CA (US); Ashish Pal, San Ramon, CA (US); El Mehdi Bazizi, San Jose, CA (US); Veeraraghavan S. Basker, Fremont, CA (US); Balasubramanian Pranatharthiharan, San Jose, CA (US); Pratik B. Vyas, Fremont, CA (US); Gregory Costrini, Flanders, NJ (US)

(73) Assignee: Applied Materials, Inc., Santa Clara, CA (US)

(21) Appl. No.: 18/609,650

(22) Filed: Mar. 19, 2024

Related U.S. Application Data
(60) Provisional application No. 63/456,278, filed on Mar. 31, 2023.
(60) Provisional application No. 63/602,735, filed on Nov. 27, 2023.

(51) Int. Cl. H01L 29/423; H01L 21/8238; H01L 27/092; H01L 29/06; H01L 29/08; H01L 29/66; H01L 29/775; H01L 29/786

(52) U.S. Cl. CPC H01L 29/42392; H01L 21/823807; H01L 21/823871; H01L 27/092; H01L 29/0665; H01L 29/0847; H01L 29/66439; H01L 29/66545; H01L 29/775; H01L 29/78696

(57) ABSTRACT

One or more embodiments of the disclosure are directed to methods of forming semiconductor devices, e.g., gate-all-around (GAA) transistors that are used in FEOL and/or BEOL processes. The processes described herein may be integrated and performed in any suitable cluster tool. Some embodiments of the disclosure are directed to cavity shaping processes. Further embodiments of the disclosure are directed to logic transistors with wrap-around backside source/drain contact.

### CROSS-REFERENCE TO RELATED APPLICATIONS

This application claims priority to U.S. Provisional Application No. 63/456,278, filed Mar. 31, 2023, and to U.S. Provisional Application No. 63/602,735, filed Nov. 27, 2023, and the entire disclosures of which are hereby incorporated by reference herein.

### TECHNICAL FIELD

Embodiments of the present disclosure pertain to the field of semiconductor devices and semiconductor device manufacturing. More particularly, embodiments of the disclosure relate to methods of reducing backside contact resistance for both NMOS and PMOS contacts.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. However, FinFETs have their own drawbacks.

As the feature sizes of transistor devices continue to shrink to achieve greater circuit density and higher performance, there is a need to improve transistor device structure and to reduce contact resistance. Examples of transistor device structures include a planar structure, a fin field effect transistor (FinFET) structure, and a gate-all-around (GAA) structure. Logic gate performance is related to the characteristics of the materials used as well as the thickness and area of the structural layers. However, as some gate characteristics are adjusted to accommodate device scaling, challenges arise.

As the semiconductor manufacturing industry moves into advanced nodes below the 2 nm node, there is a desire to improve speed and drive current of devices through reduction of contact resistance. Accordingly, there is a need for methods of reducing contact resistance.

Connecting semiconductors to a power rail is typically done on the front of the cell (e.g., the semiconductor substrate), which requires significant cell area. Backside power rail formation, connecting backside of source-epi (known as BPR Gen-II) for a logic transistor (e.g., a FinFET or GAA) has been explored for continued area scaling in next generation logic nodes.

However, currently known approaches for backside source-epi contact limits the contact interface area and contact resistivity. The limitation on contact interface area and contact resistivity leads to increase in contact resistance. Limited contact interface area also results in current crowding, leading to increased source-epi resistance. Higher source resistance and contact resistance increases overall device resistance and degrades device performance: drive-current & speed. For backside power rail formation, in order to obtain a direct bottom contact to the source/drain region, without an etch stop layer and to obtain a self-aligned bottom contact structure, there is also the need for improved methods of reducing contact resistance.

### SUMMARY

One or more embodiments of the disclosure are directed to methods of forming a semiconductor device. The method includes: forming a first liner layer on a semiconductor substrate. The semiconductor substrate comprises a source/drain region below a top surface of the semiconductor substrate and a superlattice structure formed on the top surface of the semiconductor substrate. The source/drain region comprises a silicon germanium (SiGe) layer that fills the source/drain region and a capping layer on the silicon germanium (SiGe) layer. The superlattice structure comprises a plurality of first layers of a first material and a corresponding plurality of second layers of a second material alternatingly arranged in a plurality of stacked pairs. The first liner layer forms along the plurality of first layers and the plurality of second layers. The method further includes etching a bottom portion of the first liner layer to form an etched first liner layer; epitaxially growing a second liner layer in the superlattice structure and along the first liner layer; flipping the semiconductor substrate to expose a backside surface of the semiconductor substrate; etching to remove the capping layer and the silicon germanium (SiGe) layer and form an opening within the source/drain region on the backside surface; depositing a metal silicide layer on a top surface of the opening; depositing a barrier layer along the opening of the source/drain region on the backside surface and on the metal silicide layer; and depositing a metal material on the barrier layer to fill the opening and to form a backside contact.

Additional embodiments of the disclosure are directed to a method of forming a semiconductor device. The method includes forming a first liner layer and a second liner layer on a semiconductor substrate. The semiconductor substrate comprises a source/drain region below a top surface of the semiconductor substrate and a superlattice structure formed on the top surface of the semiconductor substrate. The source/drain region comprises a silicon germanium (SiGe) layer that fills the source/drain region and a capping layer on the silicon germanium (SiGe) layer. The superlattice structure comprises a plurality of first layers of a first material and a corresponding plurality of second layers of a second material alternatingly arranged in a plurality of stacked pairs. The first liner layer forms along the plurality of first layers and the plurality of second layers and the second liner layer forms in the superlattice structure and along the first liner layer. The method further includes flipping the semiconductor substrate to expose a backside surface of the semiconductor substrate; etching a bottom portion of the first liner layer to form an etched first liner layer; etching to remove the capping layer and the silicon germanium (SiGe) layer and form an opening within the source/drain region on the backside surface; etching a cavity within the opening to remove a portion of the etched first liner layer and a portion of the second liner layer to form an etched second liner layer; depositing a metal silicide layer on a top surface of the opening of the source/drain region on the backside surface; depositing a barrier layer along the opening of the source/drain region on the backside surface and on the metal silicide layer; and depositing a metal material on the barrier layer to fill the opening and to form a backside contact.

Further embodiments of the disclosure are directed to a method of forming a semiconductor device. The method includes forming a first liner layer and a second liner layer on a semiconductor substrate. The semiconductor substrate comprises a source/drain region below a top surface of the semiconductor substrate and a superlattice structure formed on the top surface of the semiconductor substrate. The source/drain region comprises a silicon germanium (SiGe) layer that fills the source/drain region and a capping layer on the silicon germanium (SiGe) layer. The superlattice structure comprises a plurality of first layers of a first material and a corresponding plurality of second layers of a second material alternatingly arranged in a plurality of stacked pairs. The first liner layer forms along the plurality of first layers and the plurality of second layers and the second liner layer forms in the superlattice structure and along the first liner layer. The method further includes flipping the semiconductor substrate to expose a backside surface of the semiconductor substrate; selectively removing the silicon germanium (SiGe) layer to form an opening within the source/drain region on the backside surface; depositing a third liner layer in the opening; punch-through etching a portion of each of the third liner layer, the capping layer, the first liner layer, and the second liner layer to form a recessed source/drain region. The recessed source/drain region has a top portion within the superlattice structure and above the top surface of the semiconductor substrate, and a bottom portion within the semiconductor substrate below the top surface of the semiconductor substrate. The method further includes depositing a metal silicide layer on a top surface of the top portion of the recessed source/drain region; depositing a barrier layer on the bottom portion of the recessed source/drain region on the third liner layer; and depositing a metal material in the opening to form a backside contact.

### BRIEF DESCRIPTION OF THE DRAWINGS

So that the above recited features of the present disclosure can be understood in detail, a more particular description of the disclosure, briefly summarized above, may be had by reference to embodiments, some of which are illustrated in the appended drawings. It is to be noted, however, that the appended drawings illustrate one or more embodiments of this disclosure and are therefore not to be considered limiting of its scope, for the disclosure may admit to other equally effective embodiments.

FIG. 1 illustrates a process flow diagram of a method of forming a semiconductor device according to one or more embodiments;

FIG. 2A illustrates a cross-sectional view of a semiconductor substrate according to one or more embodiments;

FIG. 2B illustrates a cross-sectional view of a semiconductor substrate according to one or more embodiments;

FIG. 2C illustrates a cross-sectional view of a semiconductor substrate according to one or more embodiments;

FIG. 2D illustrates a cross-sectional view of a semiconductor substrate according to one or more embodiments;

FIG. 2E illustrates a cross-sectional view of a semiconductor substrate according to one or more embodiments;

FIG. 2F illustrates a cross-sectional view of a semiconductor substrate according to one or more embodiments;

FIG. 3 illustrates a process flow diagram of a method of forming a semiconductor device according to one or more embodiments;

FIG. 4A illustrates a cross-sectional view of a semiconductor substrate according to one or more embodiments;

FIG. 4B illustrates a cross-sectional view of a semiconductor substrate according to one or more embodiments;

FIG. 4C illustrates a cross-sectional view of a semiconductor substrate according to one or more embodiments;

FIG. 4D illustrates a cross-sectional view of a semiconductor substrate according to one or more embodiments;

FIG. 4E illustrates a cross-sectional view of a semiconductor substrate according to one or more embodiments;

FIG. 4F illustrates a cross-sectional view of a semiconductor substrate according to one or more embodiments;

FIG. 5 illustrates a process flow diagram of a method of forming a semiconductor device according to one or more embodiments;

FIG. 6A illustrates a cross-sectional view of a semiconductor substrate according to one or more embodiments;

FIG. 6B illustrates a cross-sectional view of a semiconductor substrate according to one or more embodiments;

FIG. 6C illustrates a cross-sectional view of a semiconductor substrate according to one or more embodiments;

FIG. 6D illustrates a cross-sectional view of a semiconductor substrate according to one or more embodiments;

FIG. 6E illustrates a cross-sectional view of a semiconductor substrate according to one or more embodiments;

FIG. 6F illustrates a cross-sectional view of a semiconductor substrate according to one or more embodiments;

FIG. 6G illustrates a cross-sectional view of a semiconductor substrate according to one or more embodiments;

FIG. 7A illustrates a cross-sectional view of a semiconductor substrate according to one or more embodiments;

FIG. 7B illustrates a cross-sectional view of a semiconductor substrate according to one or more embodiments;

FIG. 7C illustrates a cross-sectional view of a semiconductor substrate according to one or more embodiments;

FIG. 7D illustrates a cross-sectional view of a semiconductor substrate according to one or more embodiments; and

FIG. 8 illustrates a schematic top-view diagram of an example multi-chamber processing system according to one or more embodiments.

To facilitate understanding, identical reference numerals have been used, unless indicated otherwise to designate identical elements that are common to the Figures. It is contemplated that elements of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

In the following description, numerous specific details are set forth in order to provide a thorough understanding of the embodiments of the disclosure. It will be apparent to one skilled in the art that embodiments may be practiced without these specific details. In other instances, well-known aspects are not described in detail in order to not unnecessarily obscure embodiments.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

Spatially relative terms, such as “beneath,” “below,” “lower,” “above,” “upper” and the like, may be used herein for ease of description to describe one element's relationship to another element(s) or as illustrated in the Figures. It will be understood that the spatially relative terms are intended to encompass different orientations of a device, such as a semiconductor device, in use or operation in addition to the orientation depicted in the Figures. For example, if the device in the Figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular element, structure, material, or characteristic described in connection with the embodiment is included in at least one embodiment of the disclosure. Thus, the instances in which the phrases such as “in one or more embodiments,” “in certain embodiments,” “in one embodiment,” “in some embodiments,” or “in an embodiment” used in various places throughout this specification are not necessarily referring to the same embodiment of the disclosure. In one or more embodiments, the particular elements, structures, materials, or characteristics are combined in any suitable manner.

In the above description and illustrations and following description, numerous specific details, such as specific materials, chemistries, dimensions of the elements, etc. are set forth in order to provide thorough understanding of one or more of the embodiments of the present disclosure. It will be apparent, however, to one of ordinary skill in the art that one or more embodiments of the present disclosure may be practiced without these specific details. In other instances, semiconductor fabrication processes, techniques, materials, equipment, etc., have not been described in great detail to avoid unnecessarily obscuring this description. Those of ordinary skill in the art, with the included description, will be able to implement appropriate functionality without undue experimentation.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which layer or film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used in this specification and the appended claims, the terms “precursor,” “reactant,” “reactive gas,” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate. In one or ore more embodiments, the gate surrounds all of the nanosheets between the bottom substrate and above channels.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g., a transistor, in which the gate material surrounds the channel region on all sides. The channel region of a GAA transistor may include nanowires or nanoslabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

Generally, front-end of line (FEOL) refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a wafer. One or more embodiments of the disclosure are directed to methods of forming gate-all-around (GAA) transistors that may be used in FEOL and/or BEOL processes.

In one or more embodiments, transistors, e.g., GAA transistors, are fabricated using a standard process flow. One or more of the Figures illustrate a part or a step of a multi-step fabrication process of a semiconductor device, specifically during backside power delivery (BPD).

Connecting semiconductors to a power rail is typically done on the front of the cell, which requires significant cell area. Backside power rail formation, connecting backside of source-epi (known as BPR Gen-II) for a logic transistor (e.g., a FinFET or GAA) has been explored for continued area scaling in next generation logic nodes.

However, currently known approaches for backside source-epi contact limits the contact interface area and contact resistivity. The limitation on contact interface area and contact resistivity leads to increase in contact resistance. Limited contact interface area also results in current crowding, leading to increased source-epi resistance. Higher source resistance and contact resistance increases overall device resistance and degrades device performance: drive-current & speed.

Without intending to be bound by theory, in NMOS contacts, for example, the backside resistance is as high as 144% greater than a frontside contact resistance in the NMOS contact.

Embodiments of the present disclosure advantageously provide new integration schemes that reduce backside contact resistance. Some embodiments are directed to processes that advantageously increase contact interface area. Some embodiments are directed to processes that advantageously reduce contact resistivity. Some embodiments are directed to processes that advantageously increase contact interface area and reduce contact resistivity.

Some embodiments advantageously provide methods that reduce contact resistance in the resulting semiconductor device compared to contact resistance of a semiconductor device comprising a molybdenum silicide (MoSi) layer alone.

The processes described herein may be integrated and performed in any suitable cluster tool. The cluster tool may include process chambers for fabricating the semiconductor device, such as chambers configured for etching, deposition, atomic layer deposition (ALD), physical vapor deposition (PVD), chemical vapor deposition (CVD), oxidation, or any other suitable chamber used for the fabrication of a semiconductor device.

Some embodiments of the disclosure are directed to cavity shaping processes. In some embodiments, a method for backside contact resistance reduction includes multiple cavity shaping processes. In some embodiments, the methods for backside contact resistance reduction include a contact implant process on the backside after backside contact open. The processes described herein may be integrated methods performed in a cluster tool.

One or more embodiments of the disclosure are directed to processes including backside trench etch with sidewall liner. Some embodiments are directed to cavity shaping etching processes to recess into the front side of the source/drain region. Some embodiments are directed to selective contact epitaxial growth processes with high dose, metal silicide layer formation, and metal contact trench fill to form a backside contact.

In some embodiments, a method including a pre-clean process, a selective epitaxial growth process, and deposition of a metal silicide, and optionally, filling the opening of the backside contact with a metal, is performed in a cluster tool. Further embodiments of the disclosure are directed to logic transistors with wrap-around backside source/drain contact.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

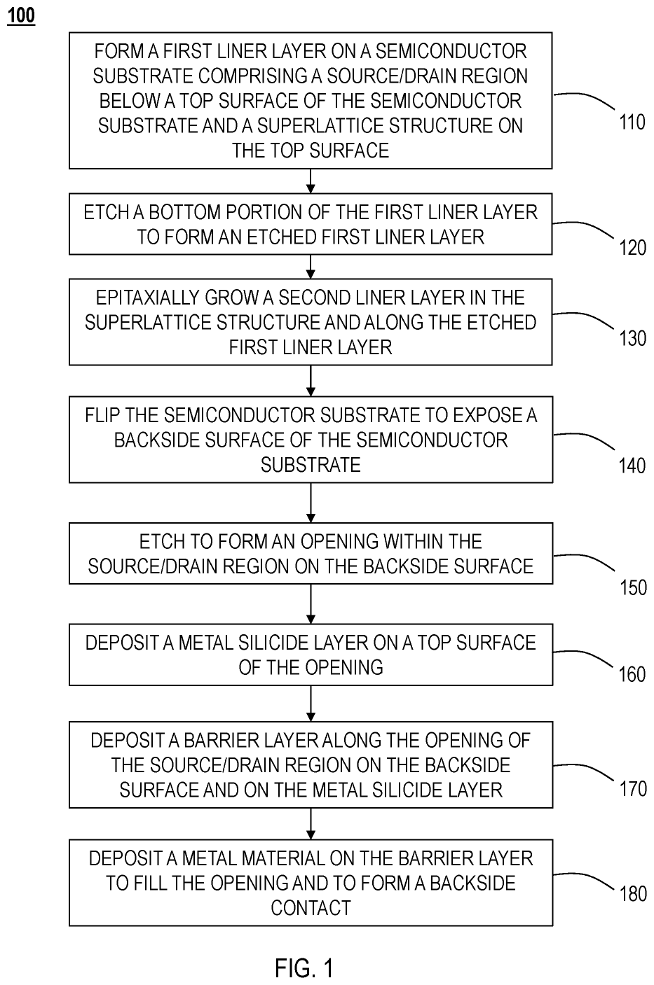

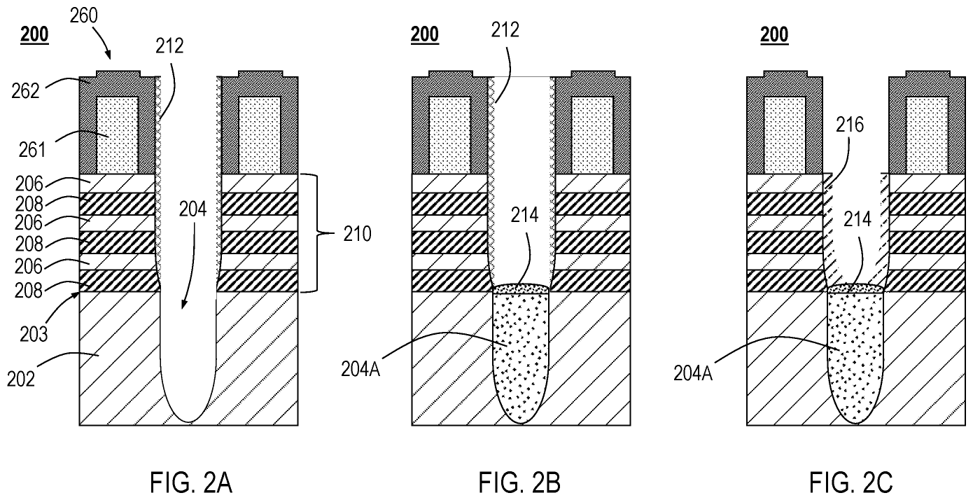

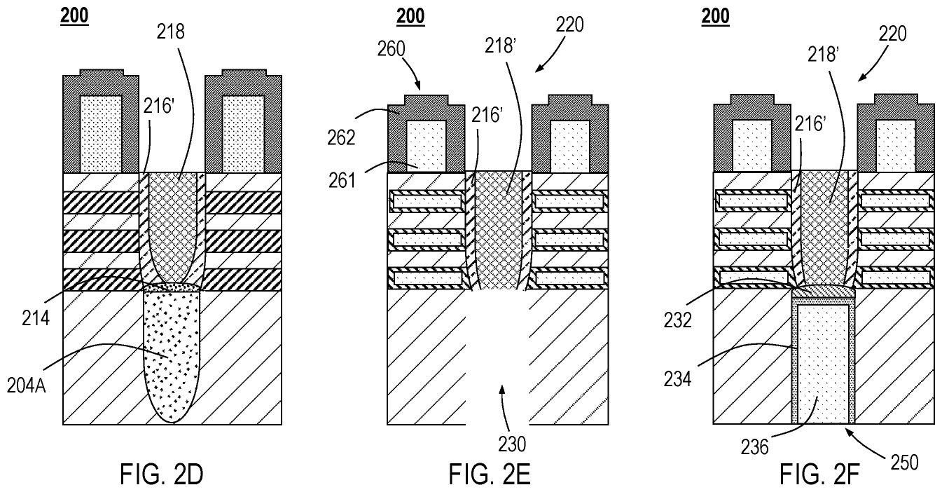

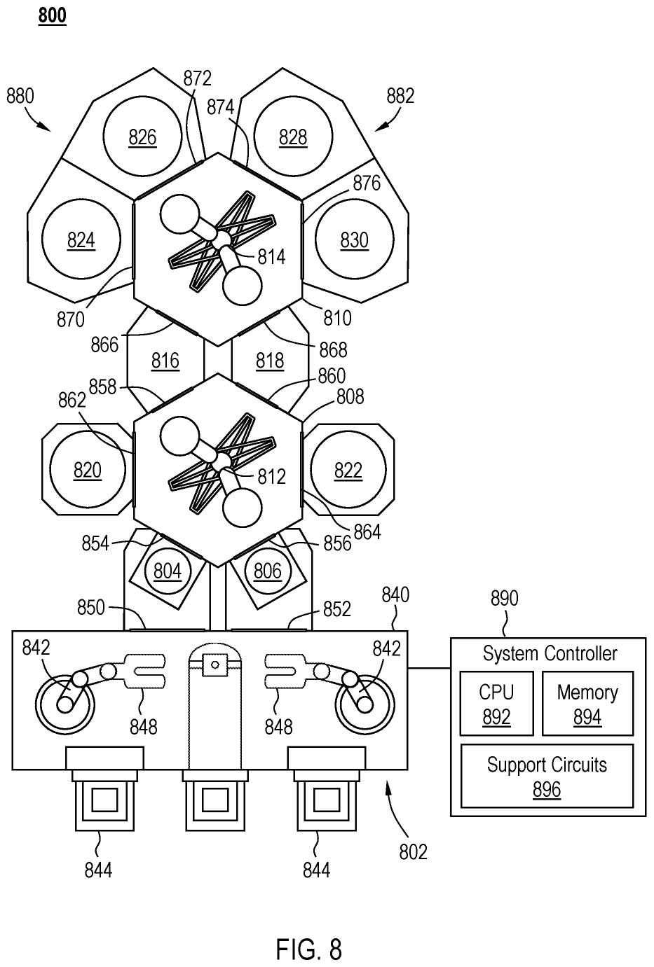

FIG. 1 illustrates a process flow diagram of a method 100 for forming a semiconductor device (e.g., semiconductor device 200) in accordance with one or more embodiments of the present disclosure. The method 100 is described below with respect to FIGS. 2A-2F, which depicts the stages of fabrication of the semiconductor device 200 in accordance with one or more embodiments of the present disclosure. FIGS. 2A-2F illustrate cross-sectional views of the semiconductor device 200. The method 100 may be part of a multi-step fabrication process. Accordingly, the method 100 may be an integrated method that is performed in any suitable process chamber coupled to a cluster tool, such as processing system 800 shown in FIG. 8. The processing system 800 may include, for example, processing chambers configured for etching, deposition, or any other suitable chamber used for the fabrication of the semiconductor device 200.

FIGS. 2A-2B illustrate stages of manufacturing the semiconductor device 200 as part of a baseline process. Stated differently, the processes illustrated in and description associated with FIGS. 2A-2B will be understood by a person of ordinary skill in the art of semiconductor manufacturing.

Referring to FIGS. 2A-2B, the baseline process includes recessing a source/drain region 204 in a semiconductor substrate 202 having a superlattice structure 210 formed on a top surface 203 of the semiconductor substrate 202. The source/drain region 204 may be defined by an aspect ratio (ratio of the depth of the source/drain region 204 to the width of the source/drain region 204). The source/drain region 204 may have any suitable aspect ratio. Next, a protective layer, e.g., a liner layer 212 is deposited along the superlattice structure 210 up to the top surface 203. The semiconductor device 200 includes a gate 260 on top of the superlattice structure 210. In one or more embodiments, the gate 260 includes a gate metal 261 surrounded by a dielectric material 262. In one or more embodiments, the dielectric material 262 is comprised of a plurality of dielectric material layers. The gate metal 261 and the dielectric material 262 may be respectively comprised of any suitable materials. In one or more embodiments, the dielectric material 262 and the liner layer 212 are comprised of the same dielectric material.

The baseline process further includes a bottom-up fill process to deposit a silicon germanium (SiGe) layer 204A to fill the source/drain region 204. The baseline process includes depositing a capping layer 214 on the silicon germanium (SiGe) layer 204A, followed by etching the semiconductor substrate 202 to remove the liner layer 212.

The method 100 begins at operation 110 comprising forming a first liner layer 216 on a semiconductor substrate 202. As will be described in further detail below, the semiconductor substrate 202 comprises a source/drain region 204 below a top surface 203 of the semiconductor substrate 202 and a superlattice structure 210 formed on the top surface 203 of the semiconductor substrate 202. The source/drain region 204 comprises a silicon germanium (SiGe) layer 204A that fills the source/drain region 204 and a capping layer 214 on the silicon germanium (SiGe) layer 204A. The superlattice structure 210 comprises a plurality of first layers 206 of a first material and a corresponding plurality of second layers 208 of a second material alternatingly arranged in a plurality of stacked pairs. At operation 110, the first liner layer 216 forms along the plurality of first layers 206 and the plurality of second layers 208.

The method 100 further includes etching a bottom portion of the first liner layer 216 to form an etched first liner layer 216′ (operation 120); epitaxially growing a second liner layer 218 in the superlattice structure 210 and along the first liner layer 216 (operation 130); flipping the semiconductor substrate 202 to expose a backside surface 220 of the semiconductor substrate 202 (operation 140); etching to remove the capping layer 214 and the silicon germanium (SiGe) layer 204A and form an opening 230 within the source/drain region 204 on the backside surface 220 (operation 150); depositing a metal silicide layer 232 on a top surface of the opening 230 (operation 160); depositing a barrier layer 234 along the opening 230 of the source/drain region 204 on the backside surface 220 and on the metal silicide layer 232 (operation 170); and depositing a metal material 236 on the barrier layer 234 to fill the opening 230 and to form a backside contact 250 (operation 180). In one or more embodiments, the method 100 consists essentially of operation 110, operation 120, operation 130, operation 140, operation 150, operation 160, operation 170, and operation 180. In one or more embodiments, the method 100 consists of operation 110, operation 120, operation 130, operation 140, operation 150, operation 160, operation 170, and operation 180.

The semiconductor substrate 202 can be any suitable substrate material. In one or more embodiments, the semiconductor substrate 202 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the semiconductor substrate 202 comprises one or more of silicon (Si), germanium (Ge), gallium (Ga), arsenic (As), indium (In), phosphorus (P), or selenium (Se). In one or more embodiments, the semiconductor substrate 202 comprises silicon (Si). Although a few examples of materials from which the semiconductor substrate 202 may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

The source/drain region 204 comprises a silicon germanium (SiGe) layer 204A that fills the source/drain region 204 and a capping layer 214 on the silicon germanium (SiGe) layer 204A. In one or more embodiments, the capping layer 214 comprises silicon (Si).

In some embodiments, the superlattice structure 210 comprises a plurality of first layers 206 of a first material and a corresponding plurality of second layers 208 of a second material alternatingly arranged in a plurality of stacked pairs. As used herein, the terms “plurality of first layers 206” and “plurality of nanosheet release layers 206” can be used interchangeably. As used herein, the terms “plurality of second layers 208” and “plurality of nanosheet channel layers 208” can be used interchangeably.

In some embodiments, the plurality of nanosheet release layers 206 and the plurality of nanosheet channel layers 208 can comprise any number of lattice matched material pairs suitable for forming the vertically stacked superlattice structure 210. In some embodiments, the superlattice structure 210 has in a range of from 1 to 5 pairs of alternating layers of nanosheet channel layers 208 and nanosheet release layers 206.

The nanosheet release layers 206 may have any suitable thickness. In one or more embodiments, each nanosheet release layer 206 has a thickness in a range of from 5 nm to 15 nm. The nanosheet channel layers 208 may have any suitable thickness. In one or more embodiments, each nanosheet channel layer 208 has a thickness in a range of from 5 nm to 15 nm.

In some embodiments, each of the nanosheet channel layers 208 independently comprises silicon (Si). Stated differently, in one or more embodiments, the second material comprises silicon (Si). In some embodiments, each of the nanosheet release layers 206 independently comprises silicon germanium (SiGe). Stated differently, in one or more embodiments, the first material comprises silicon germanium (SiGe).

Embodiments of the present disclosure advantageously provide semiconductor devices 200 which comprise a fully strained vertically stacked superlattice structure 210 having second layers 208 (e.g., the nanosheet channel layers 208) that are free or substantially free of defects. In some embodiments, the presence of defects in the nanosheet channel layers 208 are determined by a reciprocal space mapping (RSM) method. Generally, an RSM method is an x-ray diffraction method of collecting diffraction data of the vertically stacked superlattice structure 210 in which the presence of defects may be observed. As used herein, the term “substantially free” means that the nanosheet channel layers 208 are substantially free of defects as determined by an RSM method.

Referring to FIGS. 1 and 20-2F, the first liner layer 216 and the second liner layer 218 may each comprise any suitable material. In some embodiments, the first liner layer 216 comprises silicon (Si) doped with germanium (Ge), such as, for example, in a range of from 0 at. % to 60 at. % germanium (Ge), silicon (Si) doped with phosphorous (P), or silicon germanium (SiGe) doped with boron (B). In some embodiments, the second liner layer 218 comprises silicon (Si) doped with germanium (Ge), such as, for example, in a range of from 0 at. % to 60 at. % germanium (Ge), silicon (Si) doped with phosphorous (P), or silicon germanium (SiGe) doped with boron (B).

In some embodiments, the first liner layer 216 has a first dopant concentration and the second liner layer 218 has a second dopant concentration. In one or more embodiments, the first dopant concentration and the second dopant concentration are the same. In one or more embodiments, the first dopant concentration and the second dopant concentration are different. In one or more embodiments, the second dopant concentration is greater than the first dopant concentration.

Referring to FIGS. 1 and 2C, in one or more embodiments, at operation 110, the first liner layer 216 is grown or deposited along the plurality of first layers 206 and the plurality of second layers 208 using a technique, such as, but not limited to, an epitaxial growth process, ALD, CVD, PVD, MBE, MOCVD, spin-on, or other insulating layer deposition techniques known to the skilled artisan.

Referring to FIGS. 1 and 2D, the method 100 further includes etching a bottom portion of the first liner layer 216 to form an etched first liner layer 216′ (operation 120). The etching process can be any suitable etching process known to the skilled artisan. In some embodiments, the etching process comprises a wet etch process or a dry etch process. In some embodiments, the etching process comprises a wet etch process. In some embodiments, the wet etch process includes a pre-clean process. In some embodiments, the pre-clean process includes using one or more of ammonium hydroxide (NH₄OH) or water (H₂O). In some embodiments, the water (H₂O) is de-ionized water (DI). In some embodiments, the pre-clean process includes using a ratio of DI:NH₄OH in a range of from 100:1 DI:NH₄OH to 5:1 DI:NH₄OH.

In some embodiments, the pre-clean process includes using a SC-1 solution or a SC-2 solution. In one or more embodiments, the SC-1 solution comprises one or more of ozone, ammonium hydroxide or hydrogen peroxide. In one or more embodiments, the SC-2 solution comprises one or more of hydrochloric acid or hydrogen peroxide.

Referring to FIGS. 1 and 2D, in one or more embodiments, at operation 130, the method 100 includes epitaxially growing a second liner layer 218 in the superlattice structure 210 and along the first liner layer 216 (operation 130). The second liner layer 218 is grown or deposited using a technique, such as, but not limited to, an epitaxial growth process, ALD, CVD, PVD, MBE, MOCVD, spin-on, or other insulating layer deposition techniques known to the skilled artisan.

In one or more embodiments, at operation 140, the method 100 includes flipping the semiconductor substrate 202 to expose a backside surface 220 of the semiconductor substrate 202, shown in FIG. 2E.

Referring still to FIGS. 1 and 2E, in one or more embodiments, at operation 150, the method 100 includes etching to remove the capping layer 214 and the silicon germanium (SiGe) layer 204A, etching the second liner layer 218 to form an etched second liner layer 218′, and form an opening 230 within the source/drain region 204 on the backside surface 220. The etching process of operation 150 may be the same or similar etching process as operation 120.

Referring to FIGS. 1 and 2F, in one or more embodiments, at operation 160, the method 100 includes depositing a metal silicide layer 232 on a top surface of the opening 230. In one or more embodiments, the metal silicide layer 232 is grown or deposited using a technique, such as, but not limited to, an epitaxial growth process, ALD, CVD, PVD, MBE, MOCVD, spin-on, or other insulating layer deposition techniques known to the skilled artisan.

The metal silicide layer 232 can include any suitable metal silicide. In one or some embodiments, the metal silicide layer 232 comprises one or more of molybdenum silicide (MoSi), titanium silicide (TiSi), cobalt silicide (CoSi), or nickel silicide (NiSi). The metal silicide layer 232 can have any suitable thickness.

Referring still to FIGS. 1 and 2F, in one or more embodiments, at operation 170, the method 100 includes depositing a barrier layer 234 along the opening 230 of the source/drain region 204 on the backside surface 220 and on the metal silicide layer 232.

In one or more embodiments, the barrier layer 234 is grown or deposited using a technique, such as, but not limited to, an epitaxial growth process, ALD, CVD, PVD, MBE, MOCVD, spin-on, or other insulating layer deposition techniques known to the skilled artisan. In one or more embodiments, the barrier layer 234 comprises a metal nitride. The barrier layer 234 can include any suitable metal nitride. In one or more embodiments, the barrier layer 234 comprises tantalum nitride (TaN) or titanium nitride (TiN).

Referring still to FIGS. 1 and 2F, in one or more embodiments, at operation 180, the method 100 includes depositing a metal material 236 on the barrier layer 234 to fill the opening 230 and to form a backside contact 250.

In one or more embodiments, the metal material 236 is grown or deposited using a technique, such as, but not limited to, an epitaxial growth process, ALD, CVD, PVD, MBE, MOCVD, spin-on, or other insulating layer deposition techniques known to the skilled artisan. In one or more embodiments, the metal material 236 is free of seams and/or voids. In one or more embodiments, the metal material 236 comprises one or more of cobalt (Co), molybdenum (Mo), tungsten (W), nickel (Ni), or ruthenium (Ru).

The method 100 advantageously reduces contact resistance in the semiconductor device 200 compared to a contact resistance of a semiconductor device comprising a molybdenum silicide (MoSi) layer alone.

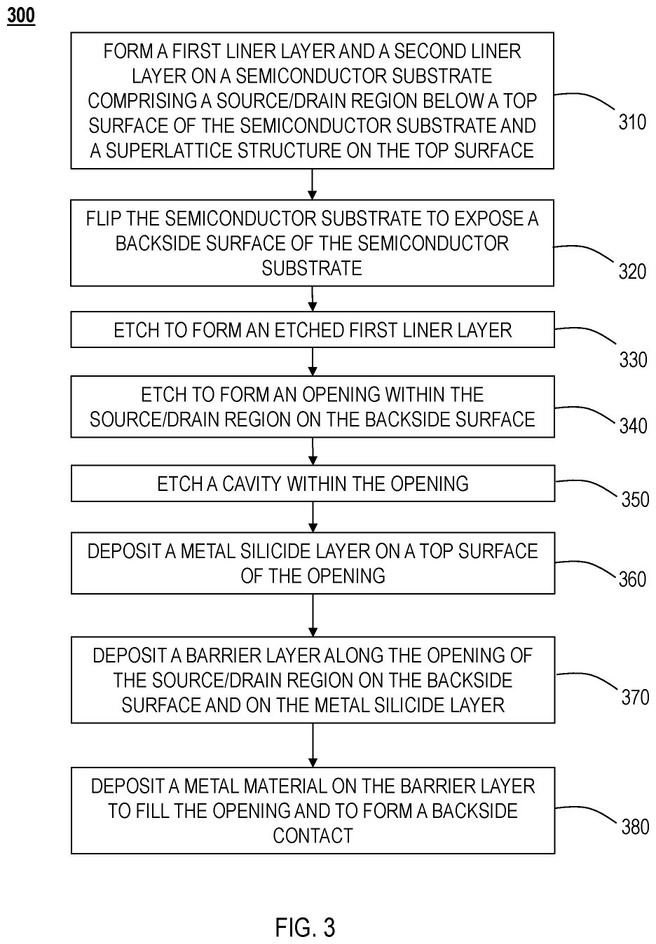

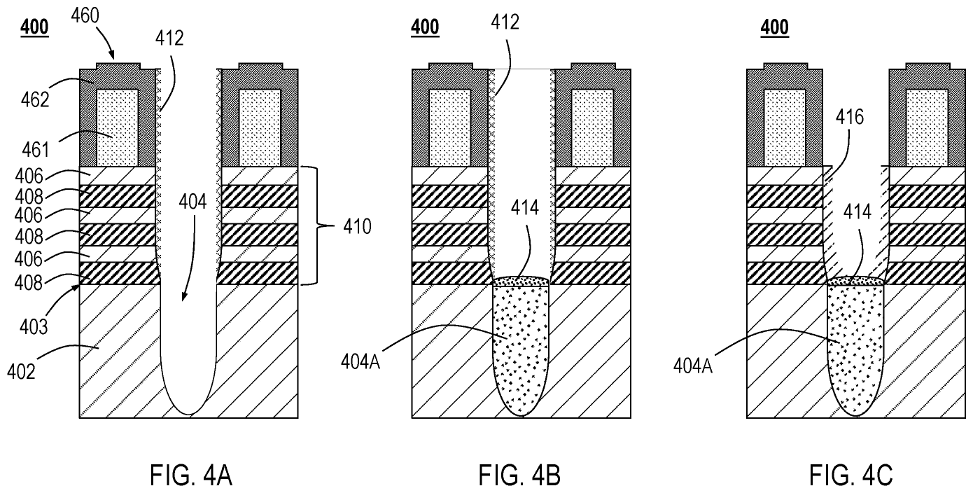

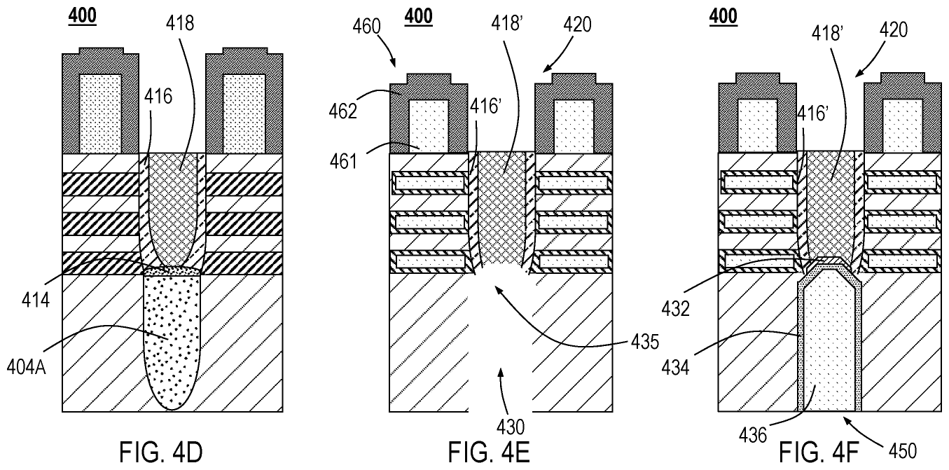

FIG. 3 illustrates a process flow diagram of a method 300 for forming a semiconductor device (e.g., semiconductor device 400) in accordance with one or more embodiments of the present disclosure. The method 300 is described below with respect to FIGS. 4A-4F, which depicts the stages of fabrication of the semiconductor device 400 in accordance with one or more embodiments of the present disclosure. FIGS. 4A-4F illustrate cross-sectional views of the semiconductor device 400. The method 300 may be part of a multi-step fabrication process. Accordingly, the method 300 may be an integrated method that is performed in any suitable process chamber coupled to a cluster tool, such as processing system 800 shown in FIG. 8. The processing system 800 may include, for example, processing chambers configured for etching, deposition, or any other suitable chamber used for the fabrication of the semiconductor device 400.

FIGS. 4A-4B illustrate stages of manufacturing the semiconductor device 400 as part of a baseline process. Stated differently, the processes illustrated in and description associated with FIGS. 4A-4B will be understood by a person of ordinary skill in the art of semiconductor manufacturing. In some embodiments, the baseline process shown in FIGS. 4A-4B is the same as the baseline process described herein with respect to FIGS. 2A-2B.

The semiconductor device 400 includes a gate 460 on top of the superlattice structure 410. In one or more embodiments, the gate 460 includes a gate metal 461 surrounded by a dielectric material 462. In one or more embodiments, the dielectric material 462 is comprised of a plurality of dielectric material layers. The gate metal 461 and the dielectric material 462 may be respectively comprised of any suitable materials. In one or more embodiments, the dielectric material 462 and the liner layer 412 are comprised of the same dielectric material.

The method 300 begins at operation 310 comprising forming a first liner layer 416 and a second liner layer 418 on a semiconductor substrate 402. The semiconductor substrate 402 comprises a source/drain region 404 below a top surface 403 of the semiconductor substrate 402 and a superlattice structure 410 formed on the top surface 403 of the semiconductor substrate 402. The source/drain region 404 comprises a silicon germanium (SiGe) layer 404A that fills the source/drain region 404 and a capping layer 414 on the silicon germanium (SiGe) layer 404A. The superlattice structure 410 comprises a plurality of first layers 406 of a first material and a corresponding plurality of second layers 408 of a second material alternatingly arranged in a plurality of stacked pairs. At operation 310, the first liner layer 416 forms along the plurality of first layers 406 and the plurality of second layers 408 and the second liner layer 418 forms in the superlattice structure 410 and along the first liner layer 416.

The method 300 further includes flipping the semiconductor substrate 402 to expose a backside surface 420 of the semiconductor substrate 402 (operation 320); etching a bottom portion of the first liner layer 416 to form an etched first liner layer 416′ (operation 330); etching to remove the capping layer 414 and the silicon germanium (SiGe) layer 404A and form an opening 430 within the source/drain region 404 on the backside surface 420 (operation 340); etching a cavity 435 within the opening 430 to remove a portion of the etched first liner layer 416′ and a portion of the second liner layer 418 to form an etched second liner layer 418′ (operation 350); depositing a metal silicide layer 432 on a top surface of the opening 430 of the source/drain region 404 on the backside surface 420 (operation 360); depositing a barrier layer 434 along the opening 430 of the source/drain region 404 on the backside surface 420 and on the metal silicide layer 432 (operation 370); and depositing a metal material 436 on the barrier layer 434 to fill the opening 430 and to form a backside contact 450 (operation 380). In one or more embodiments, the method 300 consists essentially of operation 310, operation 320, operation 330, operation 340, operation 350, operation 360, operation 370, and operation 380. In one or more embodiments, the method 300 consists of operation 310, operation 320, operation 330, operation 340, operation 350, operation 360, operation 370, and operation 380.

The semiconductor device 400 may have the same or similar components as semiconductor device 200. For example, in one or more embodiments, the semiconductor substrate 202 may be the same as the semiconductor substrate 402 in semiconductor device 400.

Referring to FIGS. 3 and 4C-4F, the first liner layer 416 and the second liner layer 418 may each comprise any suitable material. In some embodiments, the first liner layer 416 comprises silicon (Si) doped with germanium (Ge), such as, for example, in a range of from 0 at. % to 60 at. % germanium (Ge), silicon (Si) doped with phosphorous (P), or silicon germanium (SiGe) doped with boron (B). In some embodiments, the second liner layer 418 comprises silicon (Si) doped with germanium (Ge), such as, for example, in a range of from 0 at. % to 60 at. % germanium (Ge), silicon (Si) doped with phosphorous (P), or silicon germanium (SiGe) doped with boron (B).

In some embodiments, the first liner layer 416 has a first dopant concentration and the second liner layer 418 has a second dopant concentration. In one or more embodiments, the first dopant concentration and the second dopant concentration are the same. In one or more embodiments, the first dopant concentration and the second dopant concentration are different. In one or more embodiments, the second dopant concentration is greater than the first dopant concentration.

Referring to FIGS. 3 and 4C-4D, in one or more embodiments, at operation 310, the first liner layer 416 and the second liner layer 418 are grown or deposited along the plurality of first layers 406 and the plurality of second layers 408 using a technique, such as, but not limited to, an epitaxial growth process, ALD, CVD, PVD, MBE, MOCVD, spin-on, or other insulating layer deposition techniques known to the skilled artisan. In one or more embodiments, the first liner layer 416 forms along the plurality of first layers 406 and the plurality of second layers 408 and the second liner layer 418 forms in the superlattice structure 410 and along the first liner layer 416. In one or more embodiments, the first liner layer 416 is formed by ALD and the second liner layer 418 is formed by an epitaxial growth process.

Referring to FIGS. 3 and 4E, in one or more embodiments, at operation 320, the method 300 includes flipping the semiconductor substrate 402 to expose a backside surface 420 of the semiconductor substrate 402.

Referring still to FIGS. 3 and 4E, in one or more embodiments, at operation 330, the method 300 includes etching a bottom portion of the first liner layer 416 to form an etched first liner layer 416′, etching to remove the capping layer 414 and the silicon germanium (SiGe) layer 404A and form an opening 430 within the source/drain region 404 on the backside surface 420 at operation 340, and etching a cavity 435 within the opening 430 to remove a portion of the etched first liner layer 416′ and a portion of the second liner layer 418 to form an etched second liner layer 418′ at operation 350.

It has been advantageously found that etching the cavity 435 at operation 350 increases the contact interface area by 3 times, 6 times, or 9 times, as examples. Some embodiments of etching the cavity 435 at operation 350 advantageously provide contact resistivity improvement by greater than or equal to 30%, greater than or equal to 40%, or greater than or equal to 50%. It has been found that the amount of cavity etching generally corresponds to the increase in contact interface area and the amount of contact resistivity. Stated differently, it has been found that reducing the depth of the cavity (e.g., etching the cavity 435 at operation 350) by 10 nm increases the contact interface area by 3 times, etching the cavity 435 at operation 350 by 20 nm increases the contact interface area by 6 times, etching the cavity 435 at operation 350 by 30 nm increases the contact interface area by 9 times. It has also been found that etching the cavity 435 at operation 350 by 3 nm reduces contact resistivity by about 37%, etching the cavity 435 at operation 350 by 6 nm reduces contact resistivity by about 43%, etching the cavity 435 at operation 350 by 11 nm reduces contact resistivity by about 49%, and etching the cavity 435 at operation 350 by 25.5 nm reduces contact resistivity by about 55%.

The etching process of operation 330, operation 340, and operation 350 can be any suitable etching process known to the skilled artisan. In some embodiments, the etching process comprises a wet etch process or a dry etch process. In some embodiments, the etching process comprises a wet etch process. In some embodiments, the wet etch process includes a pre-clean process. In some embodiments, the pre-clean process includes using one or more of ammonium hydroxide (NH₄OH) or water (H₂O). In some embodiments, the water (H₂O) is de-ionized water (DI). In some embodiments, the pre-clean process includes using a ratio of DI:NH₄OH in a range of from 100:1 DI:NH₄OH to 5:1 DI:NH₄OH.

In some embodiments, the pre-clean process includes using a SC-1 solution or a SC-2 solution. In one or more embodiments, the SC-1 solution comprises one or more of ozone, ammonium hydroxide or hydrogen peroxide. In one or more embodiments, the SC-2 solution comprises one or more of hydrochloric acid or hydrogen peroxide.

The cavity 435 may define any suitable shape in the opening 430. In some embodiments, the cavity 435 defines a non-rectangular shape.

In some embodiments, etching the cavity 435 at operation 350 can be completed by multiple different processes, or as part of a series of processes.

In one or more embodiments, the method 300 further includes performing a contact epitaxial growth process after etching the cavity at operation 350 to fill the cavity. In one or more unillustrated embodiments, the contact epitaxial growth process includes a backside silicon etch and contact opening operation, cavity shaping at operation 350, a hardmask removal operation, a contact epitaxial growth operation, and a silicide, liner, and metal fill formation operation. Those of ordinary skill in the art, with the included description, will be able to implement appropriate functionality without undue experimentation. In one or more embodiments, the contact epitaxial growth process after etching the cavity at operation 350 to fill the cavity reduces contact resistivity by about 45%.

In one or more embodiments, the method 300 further includes repeating operation 350, e.g., etching the cavity again after the contact epitaxial growth process.

In one or more unillustrated embodiments, the series of operations when repeating operation 350 includes a backside silicon etch and contact opening operation, cavity shaping at operation 350, a hardmask removal operation, a contact epitaxial growth operation, cavity shaping at operation 350, and a silicide, liner, and metal fill formation operation. Those of ordinary skill in the art, with the included description, will be able to implement appropriate functionality without undue experimentation.

In one or more embodiments, the method 300 further includes performing a contact implant process after etching the cavity at operation 350.

In one or more unillustrated embodiments, the contact implant process includes a backside silicon etch and contact opening operation, cavity shaping at operation 350, a hardmask removal operation, a contact implant operation, and a silicide, liner, and metal fill formation operation. Those of ordinary skill in the art, with the included description, will be able to implement appropriate functionality without undue experimentation.

In one or more unillustrated embodiments, the method 300 further includes depositing a third liner layer directly on a top surface of the cavity.

In one or more unillustrated embodiments, the process of depositing the third liner layer includes a backside silicon etch and contact opening operation, cavity shaping at operation 350, a hardmask removal operation, a liner-like contact epitaxial growth operation, and a silicide, liner, and metal fill formation operation. Those of ordinary skill in the art, with the included description, will be able to implement appropriate functionality without undue experimentation.

In one or more embodiments, the methods described herein include performing a wrap-around contact process instead of etching the cavity. In specific embodiments, for example, the method 300 includes performing a wrap-around contact process instead of etching the cavity 435 at operation 350.

One or more embodiments of the disclosure are directed to methods comprising forming the first liner layer 416 forms along the plurality of first layers 406 and the plurality of second layers 408 and the second liner layer 418 forms in the superlattice structure 410 and along the first liner layer 416 (operation 310); flipping the semiconductor substrate 402 to expose a backside surface 420 of the semiconductor substrate 402 (operation 320); etching a bottom portion of the first liner layer 416 to form an etched first liner layer 416′ (operation 330); etching to remove the capping layer 414 and the silicon germanium (SiGe) layer 404A and form an opening 430 within the source/drain region 404 on the backside surface 420 (operation 340); performing a wrap-around-contact process (described further below); depositing a metal silicide layer 432 on a top surface of the opening 430 of the source/drain region 404 on the backside surface 420 (operation 360); depositing a barrier layer 434 along the opening 430 of the source/drain region 404 on the backside surface 420 and on the metal silicide layer 432 (operation 370); and depositing a metal material 436 on the barrier layer 434 to fill the opening 430 and to form a backside contact 450 (operation 380).

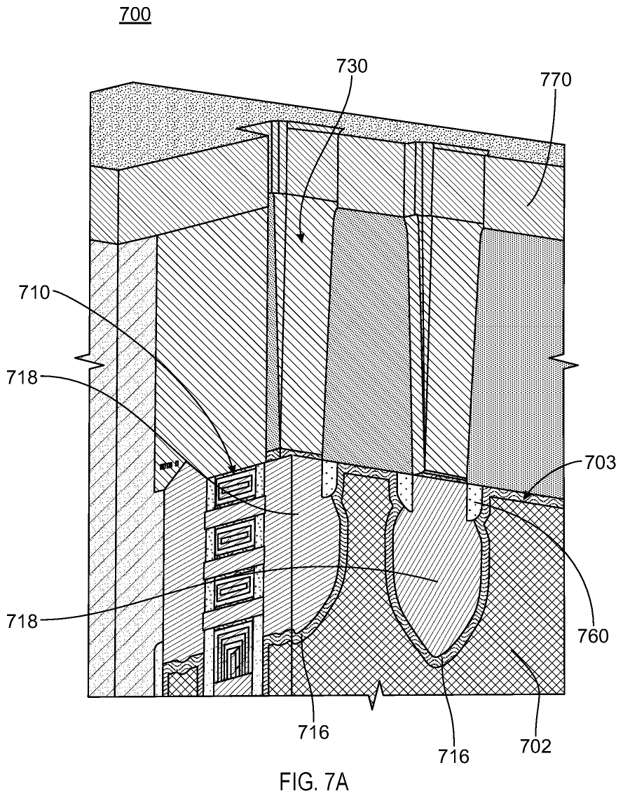

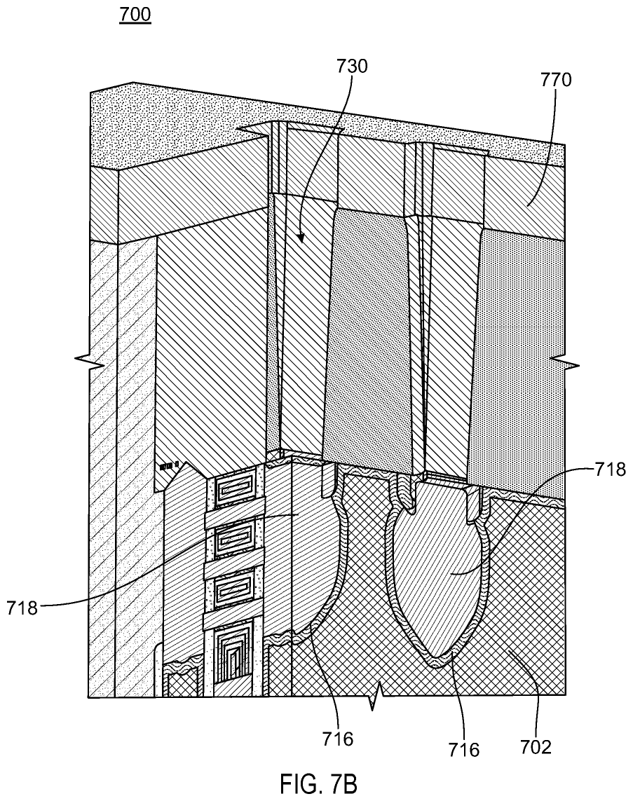

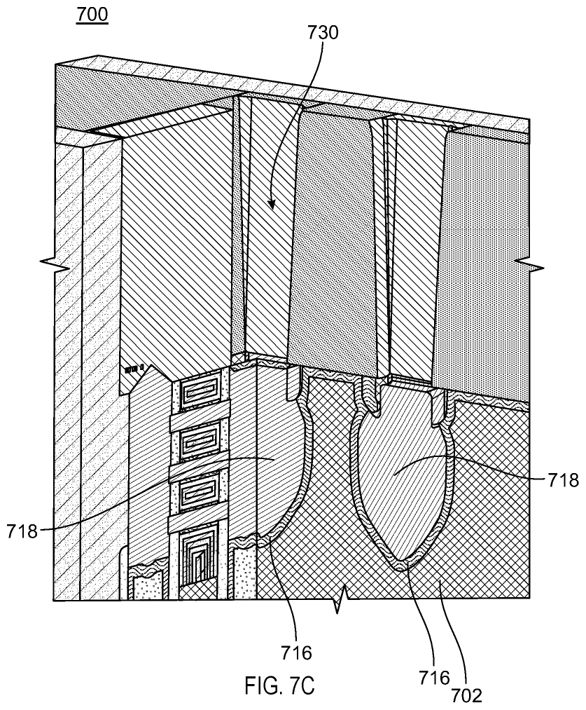

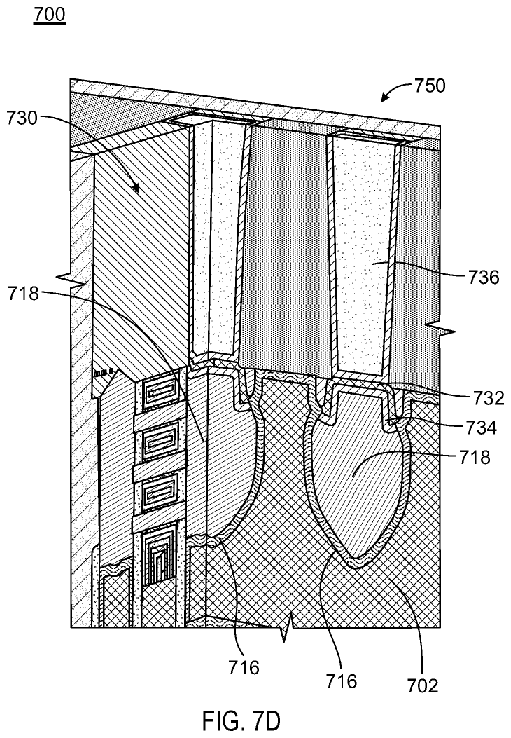

Embodiments where the methods (e.g., the method 300) include performing the wrap-around contact process instead of etching the cavity are described below with respect to FIGS. 7A-7D, which depicts the stages of fabrication of the semiconductor device 700 in accordance with one or more embodiments of the present disclosure. FIGS. 7A-7D illustrate cross-sectional views of the semiconductor device 700. The processing system 800 may include, for example, processing chambers configured for etching, deposition, or any other suitable chamber used for the fabrication of the semiconductor device 700.

In one or more unillustrated embodiments, one or more baseline operations may be performed to process the semiconductor substrate 702. In some embodiments, the baseline process includes operations such as, for example, flipping the semiconductor substrate 702 after frontside processing, chemical mechanical polishing (CMP) of the semiconductor substrate 702 to the shallow trench isolation (STI), depositing a hardmask 770, backside contact patterning, and backside silicon etching and contact opening. Those of ordinary skill in the art, with the included description, will be familiar with and able to implement appropriate functionality to the baseline process without undue experimentation.

In FIGS. 7A-7D, a semiconductor device 700 having a semiconductor substrate 702 is shown during stages of manufacture. The semiconductor device 700 may have one or more of the same elements as semiconductor devices 200, 400, and 600 having like reference numbers. For example, the semiconductor device 200 includes superlattice structure 210, and the semiconductor device 700 includes a superlattice structure 710. It will be appreciated that one or more of the processing operations used to form the semiconductor devices 200, 400, and 600 may also be used to form the semiconductor device 700.

The semiconductor substrate 702 includes the superlattice structure 710 on a top surface 703 of the semiconductor substrate 702. The superlattice structure 710 has a plurality of first layers (e.g., nanosheet release layers comprising silicon (Si) or silicon germanium (SiGe)) and a corresponding plurality of second layers (e.g., nanosheet channel layers comprising silicon (Si) or silicon germanium (SiGe)). The semiconductor device 700 is shown as already being flipped with frontside processing completed.

The semiconductor device 700 includes a first liner layer 716 and a second liner layer 718 on the first liner layer 716. In one or more embodiments, there is a spacer footing 760 in contact with each of the first liner layer 716 and the second liner layer 718. The spacer footing may include any suitable material known to the skilled artisan. In some embodiments, an opening 730 extends from the top surface 703 of the semiconductor substrate 702 through to a bottom surface of the semiconductor substrate 702. In one or more embodiments, the opening 730 extends from the top surface 703 of the semiconductor substrate 702 through a source/drain region of the semiconductor substrate 702, to the bottom surface of the semiconductor substrate 702. In one or more embodiments, a hardmask 770 is deposited on the bottom surface of the semiconductor substrate 702. The hardmask 770 may include any suitable material known to the skilled artisan.

Certain aspects of the wrap-around contact process are not described in detail in order to not unnecessarily obscure embodiments. In one or more embodiments, the wrap-around contact process includes a backside silicon etch and contact opening operation (shown in FIG. 7A). In specific embodiments, FIG. 7A shows the opening 730 extending from the top surface 703 of the semiconductor substrate 702 through a source/drain region of the semiconductor substrate 702 to the bottom surface of the semiconductor substrate 702. The opening 730 may be formed by any suitable method known to the skilled artisan. In one or more embodiments, the opening 730 is formed by one or more etching processes disclosed herein.

FIG. 7B illustrates removal of the spacer footing 760 that is in contact with each of the first liner layer 716 and the second liner layer 718. The spacer footing 760 may be removed by any suitable method known to the skilled artisan. In one or more embodiments, the spacer footing 760 is removed by one or more etching processes disclosed herein.

FIG. 7C illustrates removal of the hardmask 770. The hardmask 770 may be removed by any suitable method known to the skilled artisan. In one or more embodiments, the hardmask 770 is removed by an etching process disclosed herein.

FIG. 7D illustrates a wrap-around silicide and backside contact formation operation. In one or more embodiments, a metal silicide layer 732 is deposited a top surface of the opening 730, e.g., on the each of the first liner layer 716 and the second liner layer 718 where the spacer footing 760 was removed. In FIG. 7D, a barrier layer 734 is deposited along the opening 730 on the metal silicide layer 732; and depositing a metal material 736 on the barrier layer 734 to fill the opening 730 and to form a backside contact 750.

Those of ordinary skill in the art, with the included description and illustrated embodiments of FIGS. 7A-7D, will be able to implement appropriate functionality to the wrap-around contact process disclosed herein without undue experimentation.

In one or more embodiments, the method illustrated in FIGS. 7A-7D comprises the backside silicon etch and contact opening operation (FIG. 7A), the spacer removal operation (FIG. 7B), the hardmask removal operation (FIG. 7C), and the wrap-around silicide and backside contact formation operation (FIG. 7D). In one or more embodiments, the method illustrated in FIGS. 7A-7D consists essentially of the backside silicon etch and contact opening operation (FIG. 7A), the spacer removal operation (FIG. 7B), the hardmask removal operation (FIG. 7C), and the wrap-around silicide and backside contact formation operation (FIG. 7D). In one or more embodiments, the method illustrated in FIGS. 7A-7D consists of the backside silicon etch and contact opening operation (FIG. 7A), the spacer removal operation (FIG. 7B), the hardmask removal operation (FIG. 7C), and the wrap-around silicide and backside contact formation operation (FIG. 7D).

It has advantageously been found that the wrap-around contact process significantly improves resistivity by greater than or equal to 10% over conventional backside contact processes, e.g., depositing a molybdenum silicide (MoSi) layer alone. The wrap-around contact process of the present disclosure advantageously provides reduced current crowding, leading to improved S/D epi resistance. The wrap-around contact process of the present disclosure advantageously provides increased contact area, leading to improved contact resistance.

Referring again to FIGS. 3 and 4F, in one or more embodiments, at operation 360, the method 300 includes depositing a metal silicide layer 432 on a top surface of the opening 430, e.g., on a top surface of the cavity 435 that has been shaped. In one or more embodiments, the metal silicide layer 432 is grown or deposited using a technique, such as, but not limited to, an epitaxial growth process, ALD, CVD, PVD, MBE, MOCVD, spin-on, or other insulating layer deposition techniques known to the skilled artisan.

The metal silicide layer 432 can include any suitable metal silicide. In one or some embodiments, the metal silicide layer 432 comprises one or more of molybdenum silicide (MoSi), titanium silicide (TiSi), cobalt silicide (CoSi), or nickel silicide (NiSi). The metal silicide layer 432 can have any suitable thickness.

In FIGS. 3 and 4F, in one or more embodiments, at operation 370, the method 300 includes depositing a barrier layer 434 along the opening 430 of the source/drain region 404 on the backside surface 420 and on the metal silicide layer 432.

In one or more embodiments, the barrier layer 434 is grown or deposited using a technique, such as, but not limited to, an epitaxial growth process, ALD, CVD, PVD, MBE, MOCVD, spin-on, or other insulating layer deposition techniques known to the skilled artisan. In one or more embodiments, the barrier layer 434 comprises a metal nitride.

In FIGS. 3 and 4F, in one or more embodiments, at operation 380, the method 300 includes depositing a metal material 436 on the barrier layer 434 to fill the opening 430 and to form a backside contact 450.

In one or more embodiments, the metal material 436 is grown or deposited using a technique, such as, but not limited to, an epitaxial growth process, ALD, CVD, PVD, MBE, MOCVD, spin-on, or other insulating layer deposition techniques known to the skilled artisan. In one or more embodiments, the metal material 436 is free of seams and/or voids. In one or more embodiments, the metal material 436 comprises one or more of cobalt (Co), molybdenum (Mo), tungsten (W), nickel (Ni), or ruthenium (Ru).

The method 300 advantageously reduces contact resistance in the semiconductor device 400 compared to a contact resistance of a semiconductor device comprising a molybdenum silicide (MoSi) layer alone.

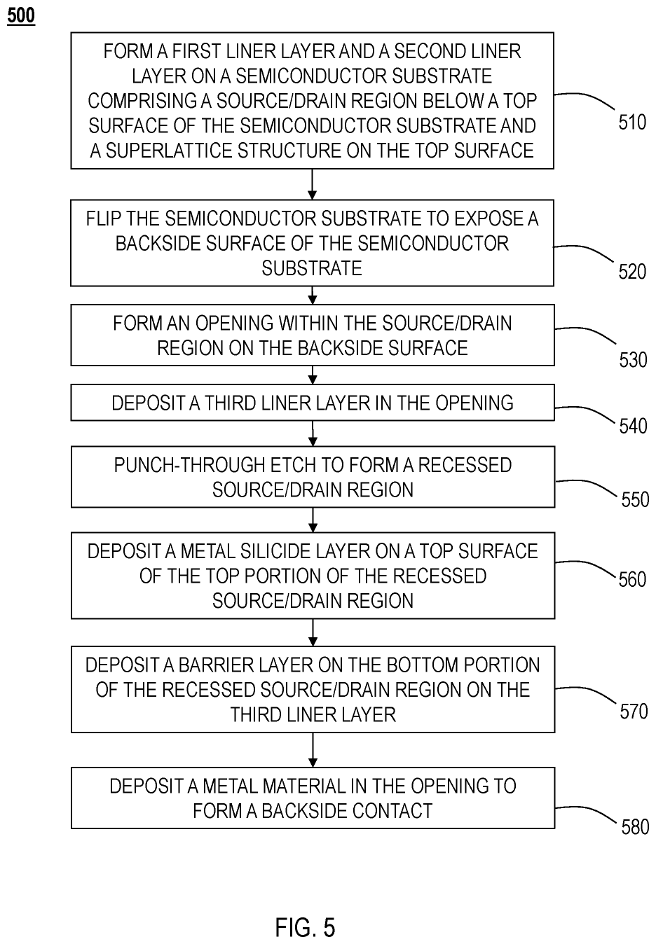

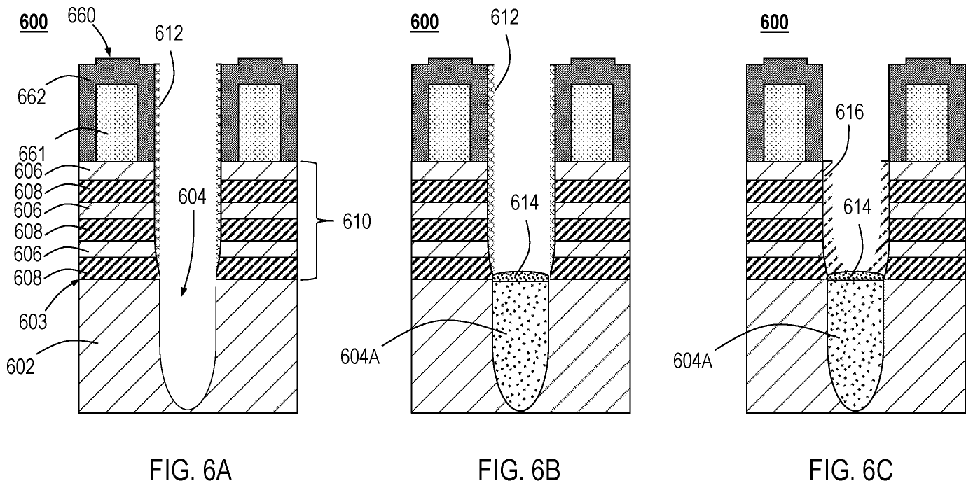

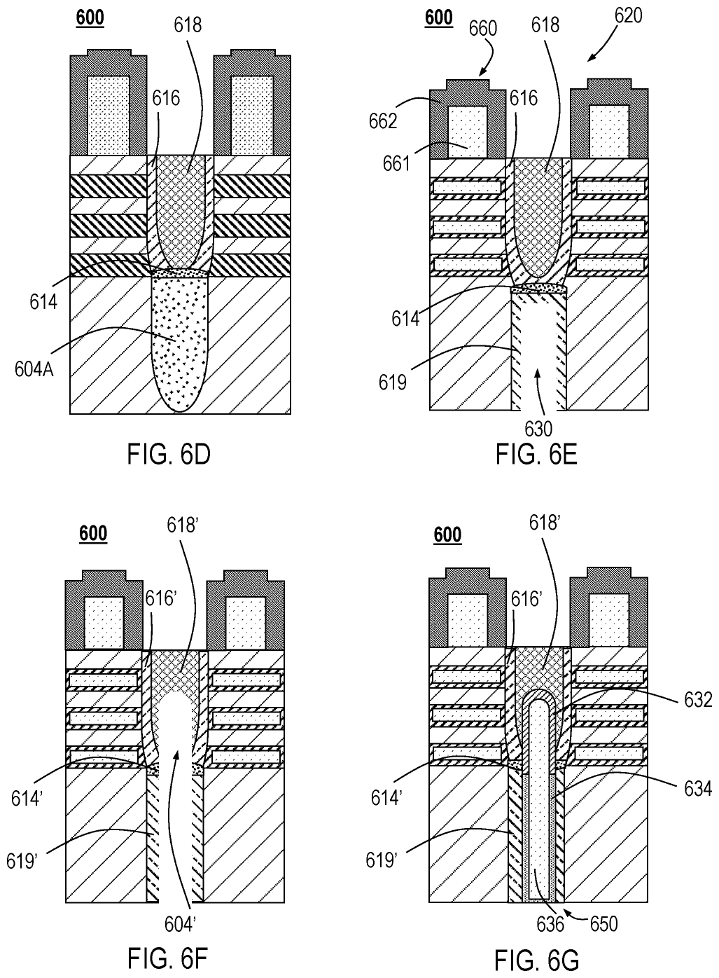

FIG. 5 illustrates a process flow diagram of a method 500 for forming a semiconductor device (e.g., semiconductor device 600) in accordance with one or more embodiments of the present disclosure. The method 500 is described below with respect to FIGS. 6A-6G, which depicts the stages of fabrication of the semiconductor device 600 in accordance with one or more embodiments of the present disclosure. FIGS. 6A-6G illustrate cross-sectional views of the semiconductor device 600. The method 500 may be part of a multi-step fabrication process. Accordingly, the method 500 may be an integrated method that is performed in any suitable process chamber coupled to a cluster tool, such as processing system 800 shown in FIG. 8. The processing system 800 may include, for example, processing chambers configured for etching, deposition, or any other suitable chamber used for the fabrication of the semiconductor device 600.

FIGS. 6A-6B illustrate stages of manufacturing the semiconductor device 600 as part of a baseline process. Stated differently, the processes illustrated in and description associated with FIGS. 6A-6B will be understood by a person of ordinary skill in the art of semiconductor manufacturing. In some embodiments, the baseline process shown in FIGS. 6A-6B is the same as the baseline process described herein with respect to FIGS. 2A-2B.

The semiconductor device 600 includes a gate 660 on top of the superlattice structure 610. In one or more embodiments, the gate 660 includes a gate metal 661 surrounded by a dielectric material 662. In one or more embodiments, the dielectric material 662 is comprised of a plurality of dielectric material layers. The gate metal 661 and the dielectric material 662 may be respectively comprised of any suitable materials. In one or more embodiments, the dielectric material 662 and the liner layer 612 are comprised of the same dielectric material.

The method 500 begins at operation 510 comprising forming a first liner layer 616 and a second liner layer 618 on a semiconductor substrate 602. As will be described in further detail below, the semiconductor substrate 602 comprises a source/drain region 604 below a top surface 603 of the semiconductor substrate 602 and a superlattice structure 610 formed on the top surface 603 of the semiconductor substrate 602. The source/drain region 604 comprises a silicon germanium (SiGe) layer 604A that fills the source/drain region 604 and a capping layer 614 on the silicon germanium (SiGe) layer 604A. The superlattice structure 610 comprises a plurality of first layers 606 of a first material and a corresponding plurality of second layers 608 of a second material alternatingly arranged in a plurality of stacked pairs. At operation 510, the first liner layer 616 forms along the plurality of first layers 606 and the plurality of second layers 608 and the second liner layer 618 forms in the superlattice structure 610 and along the first liner layer 616.

The method 500 further includes flipping the semiconductor substrate 602 to expose a backside surface 620 of the semiconductor substrate 602 (operation 520); selectively removing the silicon germanium (SiGe) layer 604A to form an opening 630 within the source/drain region 604 on the backside surface 620 (operation 530); depositing a third liner layer 619 in the opening 630 (operation 540); punch-through etching a portion of each of the third liner layer 619, the capping layer 614, the first liner layer 616, and the second liner layer 618 to form a recessed source/drain region 604′ (operation 550), the recessed source/drain region 604′ having a top portion within the superlattice structure 610 and above the top surface 603 of the semiconductor substrate 602, and a bottom portion within the semiconductor substrate 602 below the top surface 603 of the semiconductor substrate 602; depositing a metal silicide layer 632 on a top surface of the top portion of the recessed source/drain region 604′ (operation 560); depositing a barrier layer 634 on the bottom portion of the recessed source/drain region 604′ on the third liner layer 619 (operation 570); and depositing a metal material 636 in the opening 630 to form a backside contact 650 (operation 580). In one or more embodiments, the method 500 consists essentially of operation 510, operation 520, operation 530, operation 540, operation 550, operation 560, operation 570, and operation 580. In one or more embodiments, the method 500 consists of operation 510, operation 520, operation 530, operation 540, operation 550, operation 560, operation 570, and operation 580.

The semiconductor device 600 may have the same or similar components as semiconductor device 200 and/or semiconductor device 400. For example, in one or more embodiments, the semiconductor substrate 202 and/or semiconductor substrate 402 may be the same as the semiconductor substrate 602 in semiconductor device 600.

Referring to FIGS. 5 and 6C-6G, the first liner layer 616 and the second liner layer 618 may each comprise any suitable material. In some embodiments, the first liner layer 616 comprises silicon (Si) doped with germanium (Ge), such as, for example, in a range of from 0 at. % to 60 at. % germanium (Ge), silicon (Si) doped with phosphorous (P), or silicon germanium (SiGe) doped with boron (B). In some embodiments, the second liner layer 618 comprises silicon (Si) doped with germanium (Ge), such as, for example, in a range of from 0 at. % to 60 at. % germanium (Ge), silicon (Si) doped with phosphorous (P), or silicon germanium (SiGe) doped with boron (B).

In some embodiments, the first liner layer 616 has a first dopant concentration and the second liner layer 618 has a second dopant concentration. In one or more embodiments, the first dopant concentration and the second dopant concentration are the same. In one or more embodiments, the first dopant concentration and the second dopant concentration are different. In one or more embodiments, the second dopant concentration is greater than the first dopant concentration.

Referring to FIGS. 5 and 6C-6D, in one or more embodiments, at operation 510, the first liner layer 616 and the second liner layer 618 are grown or deposited along the plurality of first layers 606 and the plurality of second layers 608 using a technique, such as, but not limited to, an epitaxial growth process, ALD, CVD, PVD, MBE, MOCVD, spin-on, or other insulating layer deposition techniques known to the skilled artisan. In one or more embodiments, the first liner layer 616 forms along the plurality of first layers 606 and the plurality of second layers 608 and the second liner layer 618 forms in the superlattice structure 610 and along the first liner layer 616. In one or more embodiments, the first liner layer 616 is formed by ALD and the second liner layer 618 is formed by an epitaxial growth process.

Referring to FIGS. 5 and 6E, in one or more embodiments, the method 500 includes flipping the semiconductor substrate 602 to expose a backside surface 620 of the semiconductor substrate 602 (operation 320) and selectively removing the silicon germanium (SiGe) layer 604A to form an opening 630 within the source/drain region 604 on the backside surface 620 (operation 330). The silicon germanium (SiGe) layer 604A can be selectively removed using any suitable process to form the opening 630 within the source/drain region 604 on the backside surface 620, in accordance with one or more embodiments.

Referring still to FIGS. 5 and 6E, in one or more embodiments, the method 500 includes depositing a third liner layer 619 in the opening 630 using a technique, such as, but not limited to, an epitaxial growth process, ALD, CVD, PVD, MBE, MOCVD, spin-on, or other insulating layer deposition techniques known to the skilled artisan. In one or more embodiments, the third liner layer 619 forms along the sidewalls of the opening 630 and does not fill the opening. In one or more embodiments, the third liner layer 619 is deposited by ALD. In one or more embodiments, the third liner layer 619 comprises a dielectric material. The third liner layer 619 may include any suitable dielectric material used to protect the semiconductor substrate 202. In some embodiments, the third liner layer 619 comprises one or more of silicon nitride (SiN), silicon oxide (SiOx), silicon carbide (SiC), silicon oxycarbide (SiOC), or silicon oxycarbonitride (SiOCN).

Referring to FIGS. 5 and 6F, in one or more embodiments, the method 500 includes punch-through etching a portion of each of the third liner layer 619, the capping layer 614, the first liner layer 616, and the second liner layer 618 to form a recessed source/drain region 604′. In one or more embodiments, as a result of the punch-through etching, the recessed source/drain region 604′ includes an etched third liner layer 619′, an etched capping layer 614′, an etched first liner layer 616′, and an etched second liner layer 618′. In one or more embodiments, as a result of the punch-through etching, the recessed source/drain region 604′ has a top portion within the superlattice structure 610 and above the top surface 603 of the semiconductor substrate 602, and a bottom portion within the semiconductor substrate 602 below the top surface 603 of the semiconductor substrate 602.

The source/drain region 604 may be defined by an aspect ratio (ratio of the depth of the source/drain region 604 to the width of the source/drain region 604). The source/drain region 604 may have any suitable aspect ratio.

In one or more embodiments, the recessed source/drain region 604′ comprises an aspect ratio that is greater than the aspect ratio of the source/drain region 604. In one or more embodiments, the recessed source/drain region 604′ has a greater depth than a depth of the source/drain region 604. In one or more embodiments, the recessed source/drain region 604′ has a greater width than a width of the source/drain region 604.

In one or more embodiments, the recessed source/drain region 604′ has a greater depth and width than the respective depth and width of the source/drain region 604.

Referring to FIGS. 5 and 6G, the method 500 includes depositing a metal silicide layer 632 on a top surface of the top portion of the recessed source/drain region 604′ (operation 560); depositing a barrier layer 634 on the bottom portion of the recessed source/drain region 604′ on the third liner layer 619 (operation 570); and depositing a metal material 636 in the opening 630 to form a backside contact 650 (operation 580).

In one or more embodiments, a portion of the metal silicide layer 632 and a portion of the barrier layer 634 are in contact. In one or more embodiments, the metal silicide layer 632 forms in the top portion of the recessed source/drain region 604′ and the barrier layer 634 forms in the bottom portion of the recessed source/drain region 604′. In one or more embodiments, the metal silicide layer 632 forms entirely in the top portion of the recessed source/drain region 604′ and the barrier layer 634 forms entirely in the bottom portion of the recessed source/drain region 604′.

The method 500 advantageously reduces contact resistance in the semiconductor device 600 compared to a contact resistance of a semiconductor device comprising a molybdenum silicide (MoSi) layer alone.

FIG. 8 illustrates a schematic top-view diagram of an example of a multi-chamber processing system 800 according to embodiments of the present disclosure. Asused herein, the terms “multi-chamber processing system 800” and “processing system 800” may be used interchangeably. The processing system 800 generally includes a factory interface 802, load lock chambers 804, 806, transfer chambers 808, 810 with respective transfer robots 812, 814, holding chambers 816, 818, and processing chambers 820, 822, 824, 826, 828, 830. As detailed herein, wafers (e.g., semiconductor substrates) in the processing system 800 can be processed in and transferred between the various chambers without exposing the wafers to an ambient environment exterior to the processing system 800 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 800. Accordingly, the processing system 800 may provide for an integrated solution for some processing steps of wafers.

Existing processing systems may be suitably modified in accordance with the teachings provided herein and/or may be adapted to benefit from aspects described herein.

In the illustrated example of FIG. 8, the factory interface 802 includes a docking station 840 and factory interface robots 842 to facilitate transfer of wafers. The docking station 840 is configured to accept one or more front opening unified pods (FOUPs) 844. In some examples, each factory interface robot 842 generally comprises a blade 848 disposed on one end of the respective factory interface robot 842 configured to transfer the wafers from the factory interface 802 to the load lock chambers 804, 806.

The load lock chambers 804, 806 have respective ports 850, 852 coupled to the factory interface 802 and respective ports 854, 856 coupled to the transfer chamber 808. The transfer chamber 808 further has respective ports 858, 860 coupled to the holding chambers 816, 818 and respective ports 862, 864 coupled to processing chambers 820, 822. Similarly, the transfer chamber 810 has respective ports 866, 868 coupled to the holding chambers 816, 818 and respective ports 870, 872, 874, 876 coupled to processing chambers 824, 826, 828, 830. The ports 854, 856, 858, 860, 862, 864, 866, 868, 870, 872, 874, 876 can be, for example, slit valve openings with slit valves for passing wafers therethrough by the transfer robots 812, 814 and for providing a seal between respective chambers to prevent a gas from passing between the respective chambers. Generally, any port is open for transferring a wafer therethrough. Otherwise, the port is closed.

The load lock chambers 804, 806, transfer chambers 808, 810, holding chambers 816, 818, and processing chambers 820, 822, 824, 826, 828, 830 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 842 transfers a wafer from a FOUP 844 through a port 850 or 852 to a load lock chamber 804 or 806. The gas and pressure control system then pumps down the load lock chamber 804 or 806. The gas and pressure control system further maintains the transfer chambers 808, 810 and holding chambers 816, 818 with an interior low pressure or vacuum environment (which may include an inert gas). Hence, the pumping down of the load lock chamber 804 or 806 facilitates passing the wafer between, for example, the atmospheric environment of the factory interface 802 and the low pressure or vacuum environment of the transfer chamber 808.

With the wafer in the load lock chamber 804 or 806 that has been pumped down, the transfer robot 812 transfers the wafer from the load lock chamber 804 or 806 into the transfer chamber 808 through the port 854 or 856. The transfer robot 812 is then capable of transferring the wafer to and/or between any of the processing chambers 820, 822 through the respective ports 862, 864 for processing and the holding chambers 816, 818 through the respective ports 858, 860 for holding to await further transfer. Similarly, the transfer robot 814 is capable of accessing the wafer in the holding chamber 816 or 818 through the port 866 or 868 and is capable of transferring the wafer to and/or between any of the processing chambers 824, 826, 828, 830 through the respective ports 870, 872, 874, 876 for processing and the holding chambers 816, 818 through the respective ports 866, 868 for holding to await further transfer. The transfer and holding of the wafer within and among the various chambers can be in the low pressure or vacuum environment provided by the gas and pressure control system.

The processing chambers 820, 822, 824, 826, 828, 830 can be any appropriate chamber for processing a wafer. In some embodiments, the processing chamber 820 can be capable of performing an annealing process, the processing chamber 822 can be capable of performing a cleaning process, and the processing chambers 824, 826, 828, 830 can be capable of performing epitaxial growth processes. In some examples, the processing chamber 822 can be capable of performing a cleaning process (e.g., a preclean process), the processing chamber 820 can be capable of performing an etch process, and the processing chambers 824, 826, 828, 830 can be capable of performing respective epitaxial growth processes.

A system controller 890 is coupled to the processing system 800 for controlling the processing system 800 or components thereof. For example, the system controller 890 may control the operation of the processing system 800 using a direct control of the chambers 804, 806, 808, 816, 818, 810, 820, 822, 824, 826, 828, 830 of the processing system 800 or by controlling controllers associated with the chambers 804, 806, 808, 816, 818, 810, 820, 822, 824, 826, 828, 830. In operation, the system controller 890 enables data collection and feedback from the respective chambers to coordinate performance of the processing system 800.

The system controller 890 generally includes a central processing unit (CPU) 892, memory 894, and support circuits 896. The CPU 892 may be one of any form of a general-purpose processor that can be used in an industrial setting. The memory 894, or non-transitory computer-readable medium, is accessible by the CPU 892 and may be one or more of memory such as random-access memory (RAM), read only memory (ROM), floppy disk, hard disk, or any other form of digital storage, local or remote. The support circuits 896 are coupled to the CPU 892 and may comprise cache, clock circuits, input/output subsystems, power supplies, and the like. The various methods disclosed herein may generally be implemented under the control of the CPU 892 by the CPU 892 executing computer instruction code stored in the memory 894 (or in memory of a particular process chamber) as, for example, a software routine. When the computer instruction code is executed by the CPU 892, the CPU 892 controls the chambers to perform processes in accordance with the various methods.

Embodiments of the disclosure are directed to a non-transitory computer readable medium including instructions that, when executed by a controller of a processing chamber (e.g., controller 890 of processing system 800), causes the processing chamber (or processing system) to perform the operations of any of the methods described herein. In some embodiments, the controller 890 causes the processing system 800 to perform one or more of the operations of the method 100. In some embodiments, the controller 890 causes the processing system 800 to perform one or more of the operations of the method 300. In some embodiments, the controller 890 causes the processing system 800 to perform one or more of the operations of the method 500. In some embodiments, the controller 890 causes the processing system 800 to perform one or more of the operations of the method illustrated in FIGS. 7A-7D.

Other processing systems can be in other configurations. For example, more or fewer processing chambers may be coupled to a transfer apparatus. In the illustrated example, the transfer apparatus includes the transfer chambers 808, 810 and the holding chambers 816, 818. In other examples, more or fewer transfer chambers (e.g., one transfer chamber) and/or more or fewer holding chambers (e.g., no holding chambers) may be implemented as a transfer apparatus in a processing system.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor device, the method comprising:
forming a first liner layer on a semiconductor substrate, the semiconductor substrate comprising a source/drain region below a top surface of the semiconductor substrate and a superlattice structure formed on the top surface of the semiconductor substrate, the source/drain region comprising a silicon germanium (SiGe) layer that fills the source/drain region and a capping layer on the silicon germanium (SiGe) layer, the superlattice structure comprising a plurality of first layers of a first material and a corresponding plurality of second layers of a second material alternatingly arranged in a plurality of stacked pairs, the first liner layer forming along the plurality of first layers and the plurality of second layers;
etching a bottom portion of the first liner layer to form an etched first liner layer;
epitaxially growing a second liner layer in the superlattice structure and along the etched first liner layer;
flipping the semiconductor substrate to expose a backside surface of the semiconductor substrate;
etching to remove the capping layer and the silicon germanium (SiGe) layer and form an opening within the source/drain region on the backside surface;
depositing a metal silicide layer on a top surface of the opening;
depositing a barrier layer along the opening of the source/drain region on the backside surface and on the metal silicide layer; and
depositing a metal material on the barrier layer to fill the opening and to form a backside contact.

2. The method of claim 1, wherein the method reduces contact resistance in the semiconductor device compared to a contact resistance of a semiconductor device comprising a molybdenum silicide (MoSi) layer alone.

3. The method of claim 1, wherein the first material comprises silicon germanium (SiGe) and the second material comprises silicon (Si).

4. The method of claim 1, wherein the first liner layer has a first dopant concentration and the second liner layer has a second dopant concentration, and the second dopant concentration is greater than the first dopant concentration.

5. The method of claim 4, wherein each of the first liner layer and the second liner layer comprises silicon (Si) doped with germanium (Ge), silicon (Si) doped with phosphorous (P), or silicon germanium (SiGe) doped with boron (B).

6. The method of claim 1, wherein the capping layer comprises silicon (Si).

7. The method of claim 1, wherein the method is an integrated method performed in a cluster tool.

8. A method of forming a semiconductor device, the method comprising:
forming a first liner layer and a second liner layer on a semiconductor substrate, the semiconductor substrate comprising a source/drain region below a top surface of the semiconductor substrate and a superlattice structure formed on the top surface of the semiconductor substrate, the source/drain region comprising a silicon germanium (SiGe) layer that fills the source/drain region and a capping layer on the silicon germanium (SiGe) layer, the superlattice structure comprising a plurality of first layers of a first material and a corresponding plurality of second layers of a second material alternatingly arranged in a plurality of stacked pairs, the first liner layer forming along the plurality of first layers and the plurality of second layers and the second liner layer forming in the superlattice structure and along the first liner layer;
flipping the semiconductor substrate to expose a backside surface of the semiconductor substrate;
etching a bottom portion of the first liner layer to form an etched first liner layer;
etching to remove the capping layer and the silicon germanium (SiGe) layer and form an opening within the source/drain region on the backside surface;
etching a cavity within the opening to remove a portion of the etched first liner layer and a portion of the second liner layer to form an etched second liner layer;
depositing a metal silicide layer on a top surface of the opening of the source/drain region on the backside surface;
depositing a barrier layer along the opening of the source/drain region on the backside surface and on the metal silicide layer; and
depositing a metal material on the barrier layer to fill the opening and to form a backside contact.

9. The method of claim 8, wherein each of the first liner layer and the second liner layer comprises silicon (Si) doped with germanium (Ge), silicon (Si) doped with phosphorous (P), or silicon germanium (SiGe) doped with boron (B).

10. The method of claim 8, wherein the capping layer comprises silicon (Si).

11. The method of claim 8, wherein the cavity defines a non-rectangular shape.

12. The method of claim 8, further comprising performing a contact epitaxial growth process after etching the cavity to fill the cavity.

13. The method of claim 8, further comprising performing a contact implant process after etching the cavity.

14. The method of claim 8, further comprising depositing a third liner layer directly on a top surface of the cavity.

15. The method of claim 12, further comprising etching the cavity after the contact epitaxial growth process.

16. The method of claim 8, wherein the method is an integrated method performed in a cluster tool.

17. A method of forming a semiconductor device, the method comprising:
forming a first liner layer and a second liner layer on a semiconductor substrate, the semiconductor substrate comprising a source/drain region below a top surface of the semiconductor substrate and a superlattice structure formed on the top surface of the semiconductor substrate, the source/drain region comprising a silicon germanium (SiGe) layer that fills the source/drain region and a capping layer on the silicon germanium (SiGe) layer, the superlattice structure comprising a plurality of first layers of a first material and a corresponding plurality of second layers of a second material alternatingly arranged in a plurality of stacked pairs, the first liner layer forming along the plurality of first layers and the plurality of second layers and the second liner layer forming in the superlattice structure and along the first liner layer;
flipping the semiconductor substrate to expose a backside surface of the semiconductor substrate;
selectively removing the silicon germanium (SiGe) layer to form an opening within the source/drain region on the backside surface;
depositing a third liner layer in the opening;
punch-through etching a portion of each of the third liner layer, the capping layer, the first liner layer, and the second liner layer to form a recessed source/drain region, the recessed source/drain region having a top portion within the superlattice structure and above the top surface of the semiconductor substrate, and a bottom portion within the semiconductor substrate below the top surface of the semiconductor substrate;
depositing a metal silicide layer on a top surface of the top portion of the recessed source/drain region;
depositing a barrier layer on the bottom portion of the recessed source/drain region on the third liner layer; and
depositing a metal material in the opening to form a backside contact.

18. The method of claim 17, wherein each of the first liner layer and the second liner layer comprises silicon (Si) doped with germanium (Ge), silicon (Si) doped with phosphorous (P), or silicon germanium (SiGe) doped with boron (B).

19. The method of claim 17, wherein the capping layer comprises silicon (Si).

20. The method of claim 17, wherein the third liner layer comprises a dielectric material.
